(19) United States
(12) Patent Application Publication
(10) Pub. No.: US 2005/0180578 A1
(43) Pub. Date: Aug. 18, 2005

(54) Apparatus and method for adapting audio signal

(76) Inventors: Nam Ik Cho, Seoul (KR); Jae Joon Kim, Daejon (KR); Hae Kwang Kim, Seoul (KR); Je Ho Nam, Seoul (KR); Jin Woo Hong, Daejon (KR); Man Bae Kim, Gangwon-Do (KR); Hyoung Joong Kim, Seoul (KR); Rin Chul Kim, Seoul (KR); Jin Woong Kim, Daejon (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/512,952

(22) PCT Filed: Apr. 26, 2003
(86) PCT No.: PCT/KR03/00853

(30) Foreign Application Priority Data
Apr. 26, 2002 (KR) 10-2002-0023159

(51) Int. Cl. H04R 29/00; H03G 3/00

(52) U.S. Cl. 381/56; 381/61

(57) ABSTRACT

An apparatus and method for adapting an audio signal is provided. The apparatus adapts the audio signal to a usage environment including user's characteristic, terminal capacity and user's natural environments responsive to user's adaptation request, to thereby provide the user with a high quality of digital contents efficiently.

### TECHNICAL FIELD

The present invention relates to an apparatus and method for adapting audio signal; and, more particularly, to an apparatus and method for adapting audio signal to various usage environments, such as characteristics of a user, natural environment of a user, and the capability of a user terminal.

### BACKGROUND ART

The Moving Picture Experts Group (MPEG) suggests a new standard working item, a Digital Item Adaptation (DIA). Digital Item (DI) is a structured digital object with a standardized representation, identification and metadata, and DIA means a process for generating adapted DI by modifying the DI in a resource adaptation engine and/or descriptor adaptation engine.

Here, the resource means an asset that can be identified individually, such as video or audio clips, and image or textual asset. The resource may stand for a physical object, too. Descriptor means information related to the components or items of a DI. Also, a user is meant to include all the producer, rightful person, distributor and consumer of the DI. Media resource means a content that can be expressed digitally directly. In this specification, the term ‘content’ is used in the same meaning as DI, media resource and resource.

Conventional technologies have a problem that they cannot provide a single-source multi-use environment where one audio content is adapted to and used in different usage environments by using audio content usage information, i.e., user characteristics, natural environment of a user, and capability of a user terminal.

Here, ‘a single source’ denotes a content generated in a multimedia source, and ‘multi-use’ means various user terminals having diverse usage environments consume the ‘single source’ adaptively to their usage environment.

Single-source multi-use is advantageous because it can provide diversified contents with only one content by adapting the content adaptively to different usage environments, and further, it can reduce the network bandwidth efficiently when it provides the single source adapted to the various usage environments.

Therefore, the content provider can save unnecessary cost for producing and transmitting a plurality of contents to match the audio signal to the usage environments. On the other hand, the content consumers can be provided an audio content optimized for their hearing ability and preferences in diverse usage environment.

Conventional technologies do not take the advantage of single-source multi-user even in a Universal Multimedia Access (UMA) environment that can support the single-source multi-use. That is, the conventional technologies transmit audio contents indiscriminately without considering the usage environment, such as the natural environment of a user and capability of a user terminal. The user terminal having an audio player application, such as a windows media player, an MP3 player, a real player, etc., consumes the audio content with a format unchanged as received from the multimedia source. Therefore, the conventional technology can not support the single-source multi-use environment.

If a multimedia source provides a multimedia content in consideration of various usage environments to overcome the problems of the conventional technologies and support the single-source multi-use environment, much load is applied to the generation and transmission of the content.

### DISCLOSURE OF INVENTION

It is, therefore, an object of the present invention to provide an apparatus and method for adapting audio contents to a usage environment by using information pre-describing the usage environment of a user terminal that consumes the audio content.

In accordance with one aspect of the present invention, there is provided an apparatus for adapting audio signal for single-source multi-use, including: an audio usage environment information managing portion for acquiring, describing and managing audio usage environment information from a user terminal which consumes audio signal; and an audio adaptation portion for adapting the audio signal to the audio usage environment information to generate adapted audio signal and outputting the adapted audio signal to the user terminal, and wherein the audio usage environment information includes user characteristic information that describes the user's presentation preference for the audio signal.

In accordance with another aspect of the present invention, there is provided a method for adapting audio signal for single-source multi-use, including the steps of: a) acquiring, describing and managing audio usage environment information from a user terminal that consumes audio signal; and b) adapting the audio signal to the audio usage environment information to generate adapted audio signal and outputting the adapted audio signal to the user terminal, and wherein the audio usage environment information includes user characteristic information that describes the user's preference for the audio signal.

The technology of the present invention can provide a single-source multi-use environment where one audio content is adapted to various usage environments by using information on the environment the audio content is consumed, such as characteristics of a user, natural environment of a user, and capability of the user terminal.

### BRIEF DESCRIPTION OF DRAWINGS

The above and other objects and features of the present invention will become apparent from the following description of the preferred embodiments given in conjunction with the accompanying drawings, in which:

FIG. 1 is a block diagram illustrating a user terminal provided with an audio adaptation apparatus in accordance with an embodiment of the present invention;

FIG. 2 is a block diagram describing a user terminal that can be embodied by using the audio adaptation apparatus of FIG. 1 in accordance with an embodiment of the present invention;

FIG. 3 is a flowchart illustrating an audio adaptation process performed in the audio adaptation apparatus of FIG. 1; and

FIG. 4 is a flowchart depicting the adaptation process of FIG. 3.

### BEST MODE FOR CARRYING OUT THE INVENTION

Other objects and aspects of the invention will become apparent from the following description of the embodiments with reference to the accompanying drawings, which is set forth hereinafter.

Following description exemplifies only the principles of the present invention. Even if they are not described or illustrated clearly in the present specification, one of ordinary skill in the art can embody the principles of the present invention and invent various apparatuses within the concept and scope of the present invention.

The conditional terms and embodiments presented in the present specification are intended only to make understood the concept of the present invention, and they are not limited to the embodiments and conditions mentioned in the specification.

In addition, all the detailed description on the principles, viewpoints and embodiments and particular embodiments of the present invention should be understood to include structural and functional equivalents to them. The equivalents include not only the currently known equivalents but also those to be developed in future, that is, all devices invented to perform the same function, regardless of their structures.

For example, block diagrams of the present invention should be understood to show a conceptual viewpoint of an exemplary circuit that embodies the principles of the present invention. Similarly, all the flowcharts, state conversion diagrams, pseudo codes, and the like can be expressed substantially in a computer-readable media, and whether or not a computer or a processor is described in the specification distinctively, they should be understood to express a process operated by a computer or a processor.

The functions of various devices illustrated in the drawings including a functional block expressed as a processor or a similar concept can be provided not only by using dedicated hardware, but also by using hardware capable of running proper software. When the function is provided by a processor, the provider may be a single dedicated processor, single shared processor, or a plurality of individual processors, part of which can be shared.

The apparent use of a term, ‘processor’, ‘control’ or similar concept, should not be understood to exclusively refer to a piece of hardware capable of running software, but should be understood to include a digital signal processor (DSP), hardware, and ROM, RAM and non-volatile memory for storing software, implicatively. Other known and commonly used hardware may be included therein, too.

In the claims of the present specification, an element expressed as a “means” for performing a function described in the detailed description is intended to include all methods for performing the function including all formats of software, such as a combination of circuits that performs the function, firmware/microcode, and the like. To perform the intended function, the element is cooperated with a proper circuit for performing the software. The claimed invention includes diverse means for performing particular functions, and the means are connected with each other in a method requested in the claims. Therefore, any means that can provide the function should be understood to be an equivalent to what is figured out from the present specification.

Other objects and aspects of the invention will become apparent from the following description of the embodiments with reference to the accompanying drawings, which is set forth hereinafter. The same reference numeral is given to the same element, although the element appears in different drawings. In addition, if further detailed description on the related prior arts is thought to blur the point of the present invention, the description is omitted. Hereafter, preferred embodiments of the present invention will be described in detail.

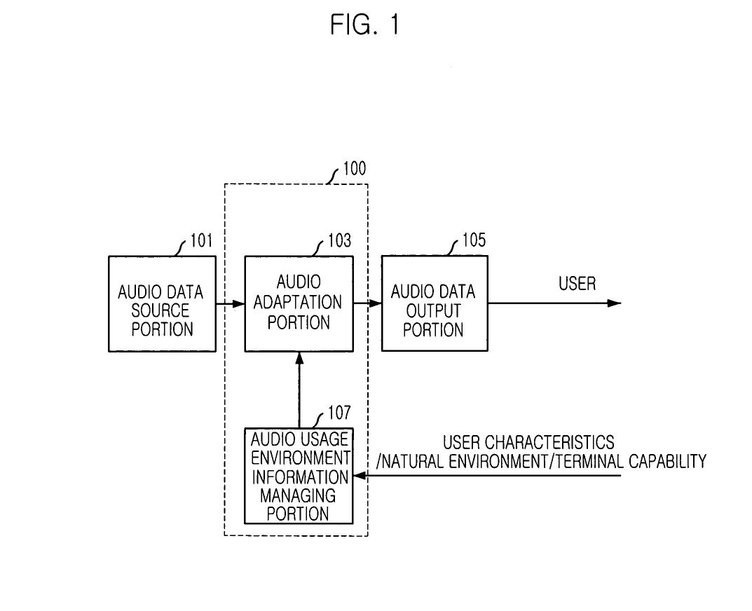

FIG. 1 is a block diagram illustrating a user terminal provided with an audio adaptation apparatus in accordance with an embodiment of the present invention. Referring to FIG. 1, the audio adaptation apparatus 100 of the embodiment of the present invention includes an audio adaptation portion 103 and an audio usage environment information managing portion 107. Each of the audio adaptation portion 103 and the audio usage environment information managing portion 107 can be provided to an audio processing system independently from each other.

The audio processing system includes laptops, notebooks, desktops, workstations, mainframe computers and other types of computers. Data processing or signal processing systems, such as Personal Digital Assistant (PDA) and wireless communication mobile stations, are included in the audio processing system.

The audio system may be any one arbitrary selected from the nodes that form a network path, e.g., a multimedia source node system, a multimedia relay node system, and an end user terminal.

The end user terminal includes an audio player, such as Windows Media Player, MP3 player and Real Player.

For example, if the audio adaptation apparatus 100 is mounted on the multimedia source node system and operated, it receives pre-described information on the usage environment in which the audio content is consumed, adapts the audio content to the usage environment, and transmits the adapted content to the end user terminal.

With respect to the audio encoding process, a process of the audio adaptation apparatus 100 processing audio data, the International organization for Standardization/International Electrotechnical Commission (ISO/IEC) standard document of the technical committee of the ISO/IEC may be included as part of the present specification as far as it is helpful in describing the functions and operations of the elements in the embodiment of the present invention.

An audio data source portion 101 receives audio data generated in a multimedia source. The audio data source portion 101 may be included in the multimedia source node system, or a multimedia relay node system that receives audio data transmitted from the multimedia source node system through a wired/wireless network, or in the end user terminal.

The audio adaptation portion 103 receives audio data from the audio data source portion 101 and adapts the audio data to the usage environment, e.g., characteristics of a user, natural environment of a user and capability of a user terminal, by using the usage environment information pre-described by the audio usage environment information managing portion 107. Here, the function of the audio adaptation portion 103 illustrated in the drawing needs not be necessarily included in any one of the node systems that forms a network path, but can be distributed to the node systems.

For example, an audio adaptation unit having a function of controlling volume, which is not related to network bandwidth, is included in the end user terminal, while an audio adaptation unit having a function of controlling the intensity of a audio signal, i.e., level of audio signal, in a temporal region, which is related to network bandwidth, may be included in the multimedia source node system.

The audio usage environment information managing portion 107 collects information from a user, a user terminal and the natural environment of a user and then describes and manages usage environment information in advance.

The usage environment information related to the function of the audio adaptation portion 103 can be distributed to the node systems that forms a network path, just as the audio adaptation portion 103.

The audio content/metadata output portion 105 outputs audio data adapted by the audio adaptation portion 103. The outputted audio data may be transmitted to an audio player of the end user terminal, or to a multimedia relay node system or the end user terminal through a wired/wireless network.

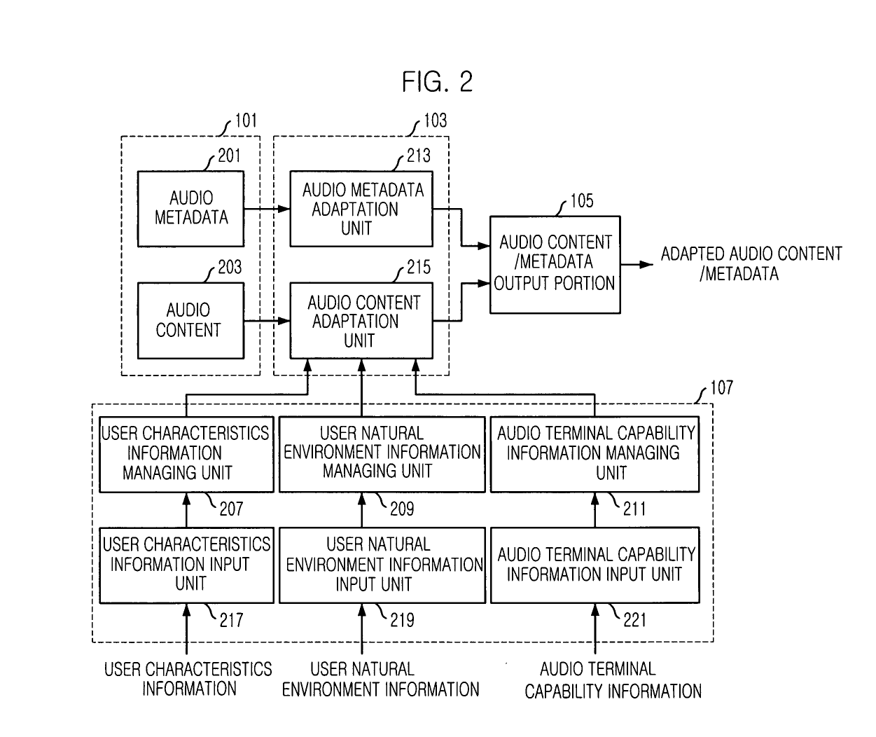

FIG. 2 is a block diagram describing a user terminal that can be embodied by using the audio adaptation apparatus of FIG. 1 in accordance with an embodiment of the present invention. As illustrated in the drawing, the audio data source portion 101 includes audio metadata 201 and an audio content 203.

The audio data source portion 101 collects audio contents and metadata from a multimedia source and stores them. Here, the audio content 203 includes diverse audio formats stored in various encoding methods, such as MPEG-1 Layer III (MP3), Audio Coder-3 (AC-3), Advanced Audio Coding (AAC), Windows Media Audio (WMA), Real Audio (RA), Code Excited Linear Predictive (CELP), etc., or transmitted in the form of streaming.

The audio metadata 201 is a description data related to a corresponding audio content, such as the encoding method of the audio content, sampling rate, number of channels (e.g., mono/stereo; 5.1 channel, etc.) and bit rate. The audio metadata can be defined and described based on extensible Markup Language (XML) schema.

The audio usage environment information managing portion 107 includes a user characteristic information managing unit 207, a user characteristic information input unit 217, a user natural environment information managing unit 209, a usage natural environment information input unit 219, an audio terminal capability information managing unit 211 and an audio terminal capability information input unit 221.

The user characteristic information managing unit 207 receives information of user characteristics, such as audibility characteristics, preferred volume of sound, preferred equalizing pattern on a frequency spectrum, etc., from the user terminal through the user characteristic information input unit 217, and manages the information of user characteristics. The inputted user characteristic information is managed in a language that can be readable mechanically, for example, an XML format.

The usage natural environment information managing unit 209 receives information of the natural environment where the audio content is consumed (which is referred to as ‘natural environment information’), through the usage natural environment information input unit 219 and manages the natural environment information. The natural environment information is managed in a language that can be readable mechanically, for example, an XML format.

The usage natural environment information input unit 219 transmits noise environment information that can be defined by a noise environment classification table which is predetermined or obtained by collecting data at a particular place, analyzing and processing the data.

The audio terminal capability information managing unit 211 receives capability information of a terminal through the audio terminal capability information input unit 221. The inputted terminal capability information is managed in a language that can be readable mechanically, for example, an XML format.

The audio terminal capability information input unit 221 transmits terminal capability information, which is pre-established in the user terminal or inputted by the user, to the audio terminal capability information managing unit 211.

The audio adaptation portion 103 includes an audio metadata adaptation unit 213 and an audio content adaptation unit 215.

The audio content adaptation unit 215 parses the usage natural environment information which is managed by the usage natural environment information managing unit 209, and performs audio signal processing based on the usage natural environment information, such as noise masking, so that the audio content could be adapted to the natural environment and be strong to noise environment.

Similarly, the audio content adaptation unit 215 parses the user characteristic information and the audio terminal capability information that are managed in the user characteristic information input unit 217 and the audio terminal capability information managing unit 211, respectively, and then adapts the audio signal suitably to the user characteristics and the capability of the user terminal.

The audio metadata adaptation processing unit 213 provides metadata needed in the audio content adaptation process, and adapts the content of a corresponding audio metadata information based on the result of audio content adaptation.

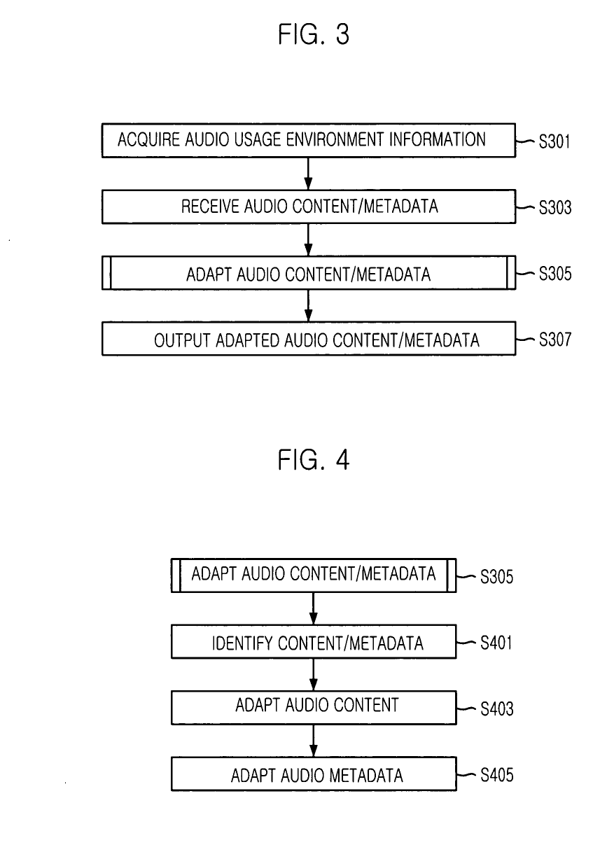

FIG. 3 is a flowchart illustrating an audio adaptation process performed in the audio adaptation apparatus of FIG. 1. Referring to FIG. 3, at step S301, the audio usage environment information managing portion 107 acquires audio usage environment information from a user, a user terminal and natural environment, and prescribes information on user characteristics, natural environment of the user and the user terminal capability.

Subsequently, at step S303, the audio data source portion 101 receives audio content/metadata. At step S305, the audio adaptation portion 103 adapts the audio content/metadata received at the step S303 suitably to the usage environment, i.e., user characteristics, natural environment of the user and the user terminal capability, by using the usage environment information described at the step S301. At step S307, the audio content/metadata output portion 105 outputs audio-data adapted at the step S305.

FIG. 4 is a flowchart depicting the adaptation process (S305) of FIG. 3. As shown in FIG. 4, at step S401, the audio adaptation portion 103 identifies an audio content and audio metadata that the audio data source portion 101 has received. At step S403, the audio adaptation portion 103 adapts the audio content that needs to be adapted suitably to the user characteristics, natural environment of the user and user terminal capability. At step S405, the audio adaptation portion 103 adapts the audio metadata corresponding to the audio content based on the result of the audio content adaptation, which is performed at the step S403.

Herein, a structure of description information that is managed in the audio usage environment information managing portion 107 is described.

In accordance with the present invention, in order to adapt an audio content to usage environment by using pre-described information of usage environment where the audio content is consumed, usage environment information, e.g., the information on the user characteristics, natural environment of the user and user terminal capability should be managed.

Table 1 describes description information for adapting audio signal structurally in accordance with an embodiment of the present invention.

TABLE 1

| Usage Environment | Elements |
|---|---|
| User Characteristic | Audibility |
| | AudibleFrequencyRange |
| | AudibleLevelRange |
| | AudioPower |
| | FrequencyEqualizer |
| | PresetEqualizer |
| | Mute |
| Natural Environment Characteristics | NoiseLevel |
| | NoiseFrequencySpectrum |
| Terminal Capabilities | AudioChannelNumber |
| | Headphone |
| | DecodersType |

Shown below is an example of syntax that expresses a description information structure of the usage environment which is managed by the audio usage environment information managing portion 107, shown in FIG. 1, based on the definition of the XML schema.

```
<element name = “UsageEnvironment”>
  <complexType>
    <all>
      <element ref = “USERCHARACTERISTICS” />
      <element
          ref = “NATURALENVIRONMENTCHARACTERISTICS”/>
      <element ref = “TERMINALCAPABILITIES”/>
    </all>
  </complexType>
</element>
```

In Table 1, the user characteristics describe audibility and preference of a user. Following shows an example of syntax that expresses a description information structure managed in the audio usage environment information managing portion 107 of FIG. 1, based on the definition of the XML schema.

```
<element name = “USERCHARACTERISTICS”>
  <complexType>
    <all>
      <element
        name = “LeftAudibility” type=”Audibility”/>
      <element
        name = “RightAudibility” type=”Audibility”/>
      <element name = “AudioPower” type = “integer”/>
      <element name = “FrequencyEqualizer”>
        <complexType>
          <sequence>
            <element name = Period type= “mpeg7:vector”/>
            <element name = Level type= “float”/>
          </sequence>
        </complexType>
      </element>
      <element name = “PresetEqualizer”>
        <complexType>
          <sequence>
            <enumeration Item = “Rock”>
            <enumeration Item = “Classic”>
            <eumeration Item = “POP>
          </sequence>
        </complexType>
      </element>
      <element name = “Mute” type = “boolean”/>
    </all>
  </complexType>
</element>
  <complexType name = “Audibility”>
    <sequence>
      <element name = “AudibleFrequencyRange”>
        <complexType>
          <mpeg7:vector dim = “2”
            type= “positiveInteger”/>
        </complexType>
      </element>
      <element name = “AudibleLevelRange”>
        <complexType>
          <mpeg7:vector dim = “2”
            type= “positiveInteger”/>
        </complexType>
      </element>
    </sequence>
  </complexType>
```

Table 2 shows elements of user characteristics.

TABLE 2

| | Elements | datatype |
|---|---|---|
| UserCharacteristics | LeftAudibility | Audibility |
| | RightAudibility | Audibility |
| | AudioPower | Integer |
| | FrequencyEqualizer | Vector |
| | PresetEqualizer | Enumeration |
| | Mute | Boolean |

In Table 2, each of the left audibility and the right audibility has an audible data type, and represents audio preference with respect to the left and right ears of a user.

The audible data type has two elements: AudibleFrequencyRange and AudibleLevelRange.

AudibleFrequencyRange describes the user's preference for a specific frequency range. StartFrequency which is a starting point of a specific frequency range and EndFrequency which is a terminating point of the frequency range are given in the unit of Hz. AudibleFrequencyRange description information represents an audible frequency range preferred by the user. If a network bandwidth given to the user is fixed, the audio adaptation portion 103 can provide audio signal of improved quality to the user by assigning more bits to the audio signal within the audible frequency range than the audio signal out of the frequency range when encoding the audio signal by using the AudibleFrequencyRange description information. Also, the audio adaptation portion 103 can reduce the network bandwidth or add additional information such as a text, an image and a video signal, to the remainder of the bandwidth by transmitting audio signal within the described frequency range based on the AudibleFrequencyRange description information.

Below example shows that the range of audible frequency preferred by a user is from 20 Hz to 2000 Hz.

```
<AudibleFrequencyRange>
    <StartFrequency>20</StartFrequency>
    <EndFrequency>2000</EndFrequency>
</AudibleFrequencyRange>
```

AudibleLevelRange describes the user's preference for a specific level range of audio signal in a temporal region. The signal level values under LowLimitedLevel which is the lowest limit of the level range of audio signal become mute, and the signal level values higher than HighLimitLevel which is the highest limit of the range of audio signal levels is restricted as an upper limit corner level. LowLimitLevel and HighLimitLevel have a normalized scale from 0.0 to 1.0. Here, 0.0 and 1.0 represent mute and the maximum signal level, respectively. Note that AudibleLevelRange description information provides the maximum value and the minimum value of the audio level the user wants to hear.

The audio adaptation portion 103 can use the AudibleLevelRange description information so that the user could experience the audio content at the best quality. For example, if the network bandwidth given to the user is fixed and the absolute difference between the maximum level and the minimum level is small, the audio adaptation portion 103 can increase the sampling rate or the number of quantization steps and transmit audio signal by using the AudibleLevelRange description information. Also, the audio adaptation portion 103 can use the bandwidth of the network efficiently by eliminating audio signal that go beyond the range of audible levels. Also, it can add other types of additional information, such as the text, the image and the video signal, to the remainder of the bandwidth.

Following example indicates that the range of audio signal level preferred by the user is from a minimum level with a value of 0.30 to the maximum level of 0.70.

```
<AudibleLevelRange>
    <LowLimitLevel>0.30</LowLimitLevel>
    <HighLimitLevel>0.70</HighLimitLevel>
</AudibleLevelRange>
```

AudioPower describes the user's preference for audio volume. AudioPower can be expressed as an integer value, or it can be a value of a normalized scale from 0.0 to 1.0, wherein 0.0 denotes mute and 1.0 represents the maximum value. The audio adaptation portion 103 controls audio signal based on the AudioPower description information which is managed in the audio usage environment information managing portion 107.

Following example shows that the audio volume preferred by the user is 0.85.

<AudioPower>0.85</AudioPower>

Description elements described hereinafter represent preference of the user with respect to audio signal. These description elements can be used in a user terminal that does not have audio processing capability.

FrequencyEqualizer describes preference with respect to a specific equalizing composition that is expressed with a frequency range and diminution or amplification value. FrequencyEqualizer description information shows the user's preference for a specific frequency. FrequencyEqualizer description information describes a frequency band and a corresponding user preference value.

If the user terminal does not have an equalizing capability, the audio adaptation portion 103 can use the FrequencyEqualizer description information to provide a desired quality to the user. For efficient bit allocation, FrequencyEqualizer description information can be used in the audio encoding process based on human frequency masking phenomena. Also, the audio adaptation portion 103 performs equalizing based on the FrequencyEqualizer description information, and transmits audio signal adapted as a result of the equalizing to the user terminal.

Period, an intrinsic attribute of FrequencyEqualizer, defines lowest limit and upper limit corner frequencies of the equalizing range that is expressed in Hz. Level, an attribute of FrequencyEqualizer, defines the attenuation or amplification of a frequency range that is expressed in a unit of decibel (dB). Level indicates a user equalizing preference value.

Following example shows a specific equalizing composition preferred by the user.

```
<FrequencyEqualizer>
  <FrequencyBand>
    <Period>
      <StartFrequency>20</StartFrequency>
      <EndFrequency>499</EndFrequency>
    </Period>
    <Level>0.8</Level>
  </FrequencyBand>
  <FrequencyBand>
    <Period>
      <StartFrequency>500</StartFrequency>
      <EndFrequency>1000</EndFrequency>
    </Period>
    <Level>0.5</Level>
  </FrequencyBand>
  <FrequencyBand>
    <Period>
      <StartFrequency>1000</StartFrequency>
      <EndFrequency>10000</EndFrequency>
    </Period>
    <Level>0.5</Level>
  </FrequencyBand>
  <FrequencyBand>
    <Period>
      <StartFrequency>10000</StartFrequency>
      <EndFrequency>20000</EndFrequency>
    </Period>
    <Level>0.0</Level>
  </FrequencyBand>
</FrequencyEqualizer>
```

PresetEqualizer describes preference for a specific equalizing composition that is expressed as verbal description on equalizer preset. That is, PresetEqualizer description information represents the user's preference for a specific type of audio that is distinguished clearly, such as rock, classical music and pop. If a user terminal does not have a capability for presetting preferred equalizer, the audio adaptation portion 103 can use PresetEqualizer description information so that the user can experience the audio content at the best quality.

As shown in the below example, the audio adaptation portion 103 can process the equalizer preset function which is set at the rock effect, and transmit the adapted audio signal to the user terminal.

<PresetEqualizer>Rock</PresetEqualizer>

Mute describes preference for processing the audio part of DI into mute. That is, Mute description information represents preference for whether to consume the audio part of a content. This function is provided most audio devices, i.e., an audio player of an end user terminal, but the audio adaptation portion 103 can use this information not to transmit audio signal in order to secure a network bandwidth.

Following example represents that the user does not use the audio part of DI.

<Mute>true</Mute>

Meanwhile, the natural environment characteristics of Table 1 describe the natural environment of a particular user. As a description information structure of the natural environment characteristics managed by the audio usage environment information managing portion 107 of FIG. 1, an exemplary syntax is expressed based on the XML schema definition.

```
<element name = “NATURALENVIRONMENTCHARACTERISTICS”>
  <complexType >
    <element name = “NoiseLevel” type = “integer”/>
    <element name = “NoiseFrequencySpectrum”>
      <complexType>
        <sequence>
          <element name = FrequencyPeriod
            type = “mpeg7:vector”/>
          <element name = FrequencyValue type = “float”/>
        </sequence>
      </complexType>
    </element>
  </complexType>
</element>
```

NoiseLevel describes the level of noise. NoiseLevel description information can be obtained by processing noise signal inputted from the user terminal. It is expressed as a dB-based sound pressure level.

The audio adaptation portion 103 can control the level of audio signal for the user terminal automatically by using the NoiseLevel description information. Meanwhile, the audio adaptation portion 103 can be mounted on an end user terminal and cope with the varying noise level of the natural environment where the terminal is located. If the noise level is relatively high, the audio adaptation portion 103 raises the size of audio signal so that the user could hear the audio signal even in the noisy environment. If the increased signal level reaches a limit predetermined by the user, the audio adaptation portion 103 stops transmitting audio signal and assigns available bandwidths to other media, such as text, image, graphic and video.

For example, if the noise of the natural environment is 20 dB, NoiseLevel is described as follows.

<NoiseLevel>20</NoiseLevel>

NoiseFrequencySpectrum description information can be obtained by processing the noise signal inputted from the user terminal, and the noise level is measured as a dB-based sound pressure level.

To perform audio coding efficiently based on the frequency masking phenomenon, the audio adaptation portion 103 can use NoiseFrequencySpectrum description information. The audio adaptation portion 103 can perform efficient audio coding by decreasing noise or increasing audio signal with respect to the frequency with much noise based on the NoiseFrequencySpectrum description information, and then it transmits adapted audio signal to the user terminal.

For example, in the below example, the first and second values of Frequency Period represent the starting frequency value and the terminating frequency value, respectively. Subsequently, Frequency Value is the power of audio and it is expressed in the unit of dB. Based on Frequency Value information, the audio adaptation portion 103 processes the function of equalizer and transmits the resultant audio signal to the user terminal.

```
<NoiseFrequencySpectrum >
  <FrequencyPeriod>20 499</FrequencyPeriod>
  <FrequencyValue>30</FrequencyValue>
  <FrequencyPeriod>500 1000</FrequencyPeriod>
  <FrequencyValue>10</FrequencyValue>
  <FrequencyPeriod>1000 10000</FrequencyPeriod>
  <FrequencyValue>50</FrequencyValue>
  <FrequencyPeriod>10000 20000</FrequencyPeriod>
  <FrequencyValue>10</FrequencyValue>
</NoiseFrequencySpectrum>
```

Meanwhile, the terminal capability of Table 1 describes the capability of a terminal in processing audio, such as audio data format, profile and diverse levels, dynamic range and composition of a speaker. Following is an exemplary syntax that describes a structure of the description information of terminal capability managed in the audio usage environment information managing portion 107 of FIG. 1, based on the XML schema definition.

```
<element name = “TERMINALCAPABILITIES”>
  <complexType>
    <element name = “AudioChannelNumer” type = integer/>
    <element name = “Headphone” type = “boolean”/>
    <element name = “DecodersType”
      type = “DecodersType”/ >
  </complexType>
</element>
<complexType name = “DecodersType”>
  <sequence>
    <element name = “DecoderType”/>
    <enumeration Item = “AAC”/>
    <enumeration Item = “MP3”/>
    <enumeration Item = “TTS”/>
    <enumeration Item = “SAOL”/>
    <element name= “Profile” type = “string”/>
    <element name= “Level” type = “string”>
    </element>
  </sequence>
</complexType>
```

Here, AudioChannelNumber information indicates the number of output channels processed by the user terminal. The audio adaptation portion 103 transmits audio signal based on the AudioChannelNumber information.

HeadPhone is information expressed as a called value. If a headphone is not used, the audio adaptation portion 103 can perform masking coding with information on the noise level of the natural environment and information on the frequency spectrum. If a headphone is used, noise from the natural environment can be reduced.

DecoderType is information representing audio format and profile/level processing capability of a terminal. The audio adaptation portion 103 transmits audio signal most suitable for the user terminal by using the DecoderType information.

As described above, the technology of the present invention can provide one single source to a plurality of usage environment by adapting the audio content to different usage environments and users with various characteristics and tastes based on the noise environment information of a user and information on the audibility and preference of a user.

While the present invention has been described with respect to certain preferred embodiments, it will be apparent to those skilled in the art that various changes and modifications may be made without departing from the scope of the invention as defined in the following claims.

1. An apparatus for adapting audio signal for single-source multi-use, comprising:
an audio usage environment information managing means for acquiring, describing and managing audio usage environment information from a user terminal which consumes audio signal; and
an audio adaptation means for adapting the audio signal to the audio usage environment information to generate adapted audio signal and outputting the adapted audio signal to the user terminal, and
wherein the audio usage environment information includes user characteristic information that describes the user's preference for the audio signal.

2. The apparatus as recited in claim 1, wherein the user characteristic information includes audibility information that indicates preference of each of the right and left ears of the user with respect to the audio signal.

3. The apparatus as recited in claim 2, wherein the audibility information includes the user's preference for a specific frequency range of the audio signal.

4. The apparatus as recited in claim 2, wherein the audibility information includes the user's preference for a specific level range of the audio signal.

5. The apparatus as recited in claim 1, wherein the user characteristic information includes the user's preference for volume of the audio signal.

6. The apparatus as recited in claim 1, wherein the user characteristic information includes the user's preference that is expressed as attenuation or amplification of the specific frequency range of the audio signal.

7. The apparatus as recited in claim 1, wherein the user characteristic information includes the user's preference for a specific type of audio, which includes rock, classical music and pop.

8. The apparatus as recited in claim 1, wherein the user characteristic information includes the user's preference for whether to consume the audio part of a multimedia content.

9. The apparatus as recited in claim 3, wherein the audio adaptation means is included in a network system that provides the adapted audio signal to the user terminal, and
wherein the audio adaptation means adapts the audio signal based on the user's preference for a specific frequency range so that more bits are assigned to the audio signal within the specific frequency range than the audio signal out of the specific frequency range.

10. The apparatus as recited in claim 3, wherein the audio adaptation means is included in a network system that provides the adapted audio signal to the user terminal, and
wherein the audio adaptation means adapts the audio signal based on the user's preference for a specific frequency range so that only audio signal within the specific frequency range are transmitted to the user terminal.

11. The apparatus as recited in claim 4, wherein the audio adaptation means is included in a network system that provides the adapted audio signal to the user terminal, and
wherein, in the user's preference for a specific level range, if the absolute difference between the maximum level and the minimum level of the specific level range is small, the audio adaptation means adapts the audio signal so that audio signal whose sampling rate is increased or whose number of quantization steps is increased would be transmitted to the user terminal.

12. The apparatus as recited in claim 4, wherein the audio adaptation means is included in a network system that provides the adapted audio signal to the user terminal, and
wherein the audio adaptation means adapts the audio signal so that, in the user's preference for a specific level range, audio signal going out of the specific level range would not be transmitted to the user terminal.

13. The apparatus as recited in claim 6, wherein the audio adaptation means is included in a network system that provides the adapted audio signal to the user terminal not having equalizing function, and
wherein the audio adaptation means adapts the audio signal so that audio signal encoded based on the preference expressed as attenuation or amplification of the specific frequency range of the audio signal would be transmitted to the user terminal.

14. The apparatus as recited in claim 7, wherein the audio adaptation means is included in a network system that provides the adapted audio signal to the user terminal without a function of presetting an equalizer, and
wherein the audio adaptation means adapts the audio signal based on the user's preference for a particular music genre so that audio signal with a preset equalizer would be transmitted to the user terminal.

15. The apparatus as recited in claim 8, wherein the audio adaptation means is included in a network system that provides the adapted audio signal to the user terminal, and
wherein if the preference indicates that the audio part of a multimedia content is not consumed, the audio adaptation means adapts the audio signal so that the audio part of the multimedia content would not be transmitted to the user terminal.

16. The apparatus as recited in claim 1, wherein the audio usage environment information further includes natural environment characteristic information that describes the natural environment where the audio signal are consumed by the user.

17. The apparatus as recited in claim 16, wherein the natural environment characteristic information includes noise level information that is obtained by processing noise signal inputted from the user terminal.

18. The apparatus as recited in claim 16, wherein the natural environment characteristic information includes noise frequency spectrum information that is obtained by processing noise signal inputted from the user terminal.

19. The apparatus as recited in claim 18, wherein the audio adaptation means is included in a network system that provides the adapted audio signal to the user terminal, and
wherein the audio adaptation means adapts audio signal based on noise level information so that the audio signal audible in the noise level would be transmitted to the user terminal, and if the level of the noise is increased and reaches to a predetermined limit, the audio adaptation means adapts the audio signal not to be transmitted to the user terminal.

20. The apparatus as recited in claim 1, wherein the audio usage environment information further includes terminal capability information that describes the capability of the user terminal in connection with the processing of the audio signal.

21. The apparatus as recited in claim 20, wherein the terminal capability information includes the number of output channels of the user terminal.

22. A method for adapting audio signal for single-source multi-use, comprising the steps of:
a) acquiring, describing and managing audio usage environment information from a user terminal that consumes audio signal; and
b) adapting the audio signal to the audio usage environment information to generate adapted audio signal and outputting the adapted audio signal to the user terminal, and
wherein the audio usage environment information includes user characteristic information that describes the user's preference for the audio signal.

23. The method as recited in claim 22, wherein the user characteristic information includes audibility information that indicates the preference of each of the right and left ears of the user with respect to the audio signal.

24. The method as recited in claim 23, wherein the audibility information includes the user's preference for a specific frequency range of the audio signal.

25. The method as recited in claim 23, wherein the audibility information includes the user's preference for a specific level range of the audio signal.

26. The method as recited in claim 22, wherein the user characteristic information includes the user's preference for volume of the audio signal.

27. The method as recited in claim 22, wherein the user characteristic information includes the user's preference that is expressed as attenuation or amplification of the specific frequency range of the audio signal.

28. The method as recited in claim 22, wherein the user characteristic information includes the user's preference for a particular music genre of audio, which includes rock, classical music, and pop.

29. The method as recited in claim 22, wherein the user characteristic information includes the user's preference for whether to consume the audio part of a multimedia content.

30. The method as recited in claim 24, wherein the step b) is performed in a network system that provides the adapted audio signal to the user terminal, and
wherein the audio signal is adapted based on the user's preference for a specific frequency range so that more bits are assigned to the audio signal within the specific frequency range than the audio signal out of the specific frequency range would be transmitted to the user terminal.

31. The method as recited in claim 24, wherein the step b) is performed in a network system that provides adapted the audio signal to the user terminal, and
wherein the audio signal are adapted based on the user's preference for a specific frequency range so that only audio signal within the specific frequency range are transmitted to the user terminal.

32. The method as recited in claim 25, wherein the step b) is performed in a network system that provides the adapted audio signal to the user terminal, and
wherein, in the user's preference for a specific level range, if the absolute difference between the maximum level and the minimum level of the specific level range is small, the audio signal are adapted so that audio signal whose sampling rate is increased or whose number of quantization steps is increased would be transmitted to the user terminal.

33. The method as recited in claim 25, wherein the step b) is performed in a network system that provides the adapted audio signal to the user terminal, and
wherein the step b) adapts audio signal so that the audio signal going out of the specific level range in the user's preference for a specific level range would not be transmitted to the user terminal.

34. The method as recited in claim 27, wherein the step b) is performed in a network system that provides the adapted audio signal to a user terminal not having equalizing function, and
wherein in the step b), the audio signal are adapted so that audio signal encoded based on the preference expressed as diminution or amplification of the specific frequency range of the audio signal would be transmitted to the user terminal.

35. The method as recited in claim 28, wherein the step b) is performed in a network system that provides the adapted audio signal to a user terminal without a function of presetting equalizer, and
wherein the audio signal are adapted based on the user's preference for a particular music genre so that audio signal with a preset equalizer would be transmitted to the user terminal.

36. The method as recited in claim 29, wherein the step b) is performed in a network system that provides the adapted audio signal to the user terminal, and
wherein if the preference indicates that the audio part of a multimedia content is not consumed, audio signal are adapted so that the audio part of the multimedia content would not be transmitted to the user terminal.

37. The method as recited in claim 22, wherein the audio usage environment information further includes natural environment characteristic information that describes the natural environment where the audio signal are consumed by the user.

38. The method as recited in claim 22, wherein the natural environment characteristic information includes noise level information that is obtained by processing noise signal inputted from the user terminal.

39. The method as recited in claim 37, wherein the natural environment characteristic information includes noise frequency spectrum information that is obtained by processing noise signal inputted from the user terminal.

40. The method as recited in claim 38, wherein the step b) is performed in a network system that provides the adapted audio signal to the user terminal, and
wherein audio signal are adapted based on the noise level information so that the audio signal audible in the noise level would be transmitted to the user terminal, and if the level of the noise is increased and reaches to a predetermined limit, the audio signal are adapted not to be transmitted to the user terminal.

41. The method as recited in claim 22, wherein the audio usage environment information includes terminal capability information that describes the capability of the user terminal in connection with the processing of the audio signal.

42. The method as recited in claim 41, wherein the terminal capability information includes the number of output channels of the user terminal.
